(19) United States
(12) Patent Application Publication
(10) Pub. No.: US 2004/0175897 A1
(43) Pub. Date: Sep. 9, 2004

(54) Optimized buried strap formation utilizing polycrystalline SixC1-x

(76) Inventors: Paul Wensley, Melton Mowbray (GB); Kevin McStay, Hopewell Junction, NY (US)

Correspondence Address: SLATER & MATSIL, L.L.P., 17950 PRESTON RD, SUITE 1000, DALLAS, TX, 75252-5793, US

(21) Appl. No.: 10/384,327

(22) Filed: Mar. 7, 2003

(51) Int. Cl. H01L 21/20

(52) U.S. Cl. 438/386

(57) ABSTRACT

A method of forming a buried strap for a memory device includes in-situ doping a semiconductor material during deposition with propane and a dopant to form a polycrystalline buried strap comprising carbon. A barrier layer comprising carbon, such as SiC or SiₓC₁₋ₓ, or both, is formed within the buried strap that controls or slows down dopants from migrating to an adjacent outdiffusion region within the substrate. A heavily doped polysilicon region may be formed beneath the carbon-containing buried strap, which reduces the trench semiconductor material resistance.

### TECHNICAL FIELD

Embodiments of the present invention relate generally to the fabrication of integrated circuits (IC's), and more particularly to the fabrication of memory devices.

### BACKGROUND

Semiconductor devices are used in a variety of electronic applications, such as personal computers, televisions and stereo equipment, and cellular phones, for example. One semiconductor product widely used in electronic systems for storing data is a semiconductor memory device, and a common type of semiconductor memory device is a dynamic random access memory (DRAM). A DRAM typically includes millions or billions of individual DRAM cells arranged in an array, with each cell storing one bit of data. A DRAM memory cell typically includes an access field effect transistor (FET) and a storage capacitor. The access FET allows the transfer of data charges to and from the storage capacitor during reading and writing operations. In addition, the data charges on the storage capacitor are periodically refreshed during a refresh operation.

DRAM storage capacitors are typically formed by etching deep trenches in a substrate. A plurality of layers of conductive, insulating, and semiconductive materials are deposited, patterned and etched in order to produce a storage capacitor that is adapted to store a bit of data, represented by a one or zero. Prior art DRAM designs typically comprise an access FET disposed in a subsequent layer to the side of the storage capacitor. More recent DRAM designs involve disposing the access FET directly above the storage capacitor in the upper part of the trench, which conserves surface area, resulting in the ability to place more DRAM cells on a single chip.

An element known as a buried strap is a conductive path that electrically couples a memory cell storage capacitor to the drain of an access transistor. In vertical access transistor technology, the capacitor is formed in a lower part of the trench, and the access transistor is formed in the upper part of the trench. A thick dielectric layer called trench top oxide (TTO) typically forms the electrical isolation between capacitor and transistor. The strap is buried below the wafer surface in the trench sidewall below the TTO. Dopant outdiffusion from the strap into the silicon sidewall creates a doped area and forms the drain of the access transistor.

Prior art buried strap formation typically involves depositing polysilicon over the deep trench capacitor within a deep trench. A problem in prior art trench poly deposition is that the resistance can be excessive due to the narrow dimensions and difficulty getting enough dopant into the trench. Additional dopant to reduce resistance, often added in the prior art, causes too much diffusion into the substrate, forming shorts or negatively impacting device performance.

What is needed in the art is a method of forming a buried strap that allows for improved control of outdiffusion, and reduces the buried strap resistance.

### SUMMARY OF THE INVENTION

These and other problems are generally solved or circumvented, and technical advantages are generally achieved, by preferred embodiments of the present invention, in which propane and a dopant are added to the buried strap deposition process, resulting in the formation of a SiₓC₁₋ₓ and/or SiC barrier layer at the interface of the buried strap and the silicon sidewall, and between the buried strap region and the deeper regions of the trench.

In accordance with a preferred embodiment of the present invention, a method for forming a buried strap of a memory device includes providing a memory device, the memory device having a substrate with at least one trench capacitor formed therein, the trench capacitor including a fill material comprising a first semiconductor material. The first semiconductor material of the at least one trench capacitor is recessed below a top surface of the substrate, and a second semiconductor material is deposited over the recessed first semiconductor fill material in the presence of a carbon-containing gas, wherein the second semiconductor material forms a buried strap.

In accordance with another preferred embodiment of the present invention, a method of manufacturing a memory device includes providing a workpiece, the workpiece comprising a semiconductor material substrate, and forming at least one memory cell within the workpiece, the at least one memory cell comprising a trench capacitor, the trench capacitor including a fill material comprising a first semiconductor material. The method includes recessing the first semiconductor material of the at least one trench capacitor below a top surface of the substrate, and depositing a second semiconductor material over the recessed first semiconductor fill material in the presence of a carbon-containing gas and a dopant, wherein the second semiconductor material forms a buried strap.

In accordance with yet another preferred embodiment of the present invention, a memory device includes a workpiece, the workpiece comprising a semiconductor material substrate, and at least one memory cell within the workpiece, the at least one memory cell comprising a trench capacitor, the trench capacitor including a fill material comprising a first semiconductor material, and the fill material being recessed below a top surface of the substrate. The memory device includes a second semiconductor material disposed over and abutting the recessed first semiconductor fill material, wherein the second semiconductor material forms a buried strap, wherein the second semiconductor material comprises a dopant and SiₓC₁₋ₓ.

Advantages of embodiments of the invention include the ability to control the crystalline structure and carbon content in the SiₓC₁₋ₓ film of the buried strap, which is in-situ doped and readily anneals and etches. The carbon content and dopant of the buried strap may be varied, which allows for the formation of a conducting interface and inhibition of re-crystallization of the region of buried strap/outdiffusion area of substrate interface, by carbon pinning grains that are formed in the buried strap. The carbon in the buried strap allows the top portion of the deep trench semiconductor fill material to be heavily doped. The carbon in the buried strap also allows the bottom portion of the deep trench to be more heavily doped, by controlling the movement of dopant from the bottom portion up into the buried strap. Furthermore, preferably a low pressure chemical vapor deposition (LPCVD) deposition process is used, which advantageously requires a low temperature and pressure. Outdiffusion of dopants from the buried strap may be controlled by varying the carbon content, thickness, and crystal structure of the buried strap. By the same method, the resistance of the buried strap may be lowered, particularly at low temperatures.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIGS. 1 through 5 show cross-sectional views of a DRAM device at various stages of manufacturing, in accordance with an embodiment of the present invention, wherein less than 50% carbon is introduced to the buried strap during deposition, forming a SiₓC₁₋ₓ barrier layer;

FIG. 6 shows a cross-sectional view of a DRAM device, in an embodiment where 50% carbon is introduced to the buried strap during deposition, forming a SiC barrier layer; and

FIG. 7 illustrates an embodiment wherein both a SiC barrier layer and a SiₓC₁₋ₓ barrier layer are formed during the buried strap deposition.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that embodiments of the present invention provide many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely a DRAM. The invention may also be applied, however, to other memory devices and semiconductor devices.

A description of preferred embodiments of the present invention will be discussed, followed by a discussion of some advantages of embodiments of the invention. A cross-section of one memory cell is shown in each figure, although many other memory cells and components of memory cells may be present in the semiconductor devices shown.

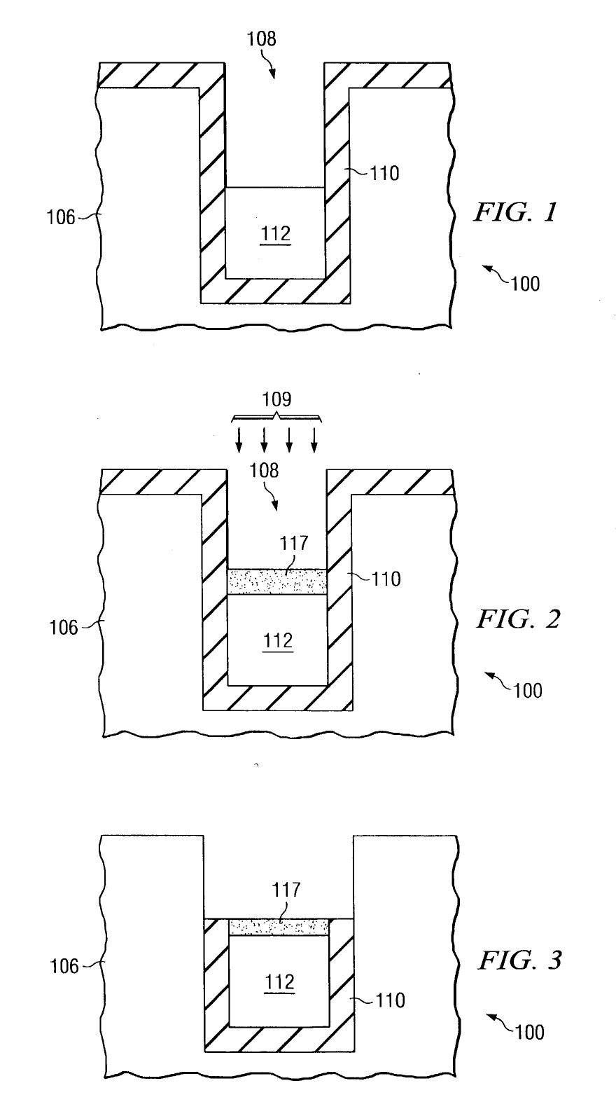

With reference to FIG. 1, a semiconductor wafer 100 having a substrate 106 is provided. The substrate 106 typically comprises a semiconductor material such as single-crystal silicon, and may include other conductive layers or other semiconductor elements such as transistors or diodes, as examples. The substrate 106 may alternatively comprise a workpiece or compound semiconductors such as GaAs, InP, Si/Ge, SiC, as examples.

A pad nitride (not shown) may be deposited over the semiconductor substrate 106. The pad nitride may comprise silicon nitride deposited in a thickness of 100-300 nm, for example. Alternatively, the pad nitride may comprise other nitrides or oxides, as examples.

At least one trench 108 is formed in the semiconductor substrate 106. The trench 108 may have a high aspect ratio, e.g., the depth may be much greater than the width. For example, the trench 108 may have a width of about 100 nm or smaller, and a depth of about 10 μm deep or more below the top surface of the substrate 106. The trench 108 may have an oval shape when viewed from the top surface of the wafer 100, and alternatively, the trench 108 may comprise other shapes, such as square, rectangular, or circular, as examples. The trench 108 may form a storage node or capacitor of a memory cell, such as in a DRAM, for example.

A first oxide layer 110 is deposited or formed within the trench 108, as shown in FIG. 1. In the lower part of the trench 108, a storage capacitor will be formed. The first oxide layer 110 preferably comprises silicon dioxide, and may alternatively comprise other insulative materials, as examples. The first oxide layer 110 may be about 40 nm thick or less, for example. The first oxide layer 110 will function as a trench isolation collar for the DRAM storage cell that will be formed by trench 108 in a vertical DRAM, for example. The trench isolation collar serves to isolate devices on the wafer 100 from one another.

A first semiconductor material 112 is deposited within the trenches 108 over the first oxide layer 110. The first semiconductor material 112 preferably comprises polysilicon deposited in a thickness of around 2000 Å, for example, and may alternatively comprise other semiconductor materials, for example. A chemical-mechanical polish (CMP) may be performed to remove the first semiconductor material 112 from the top surface of the wafer 100, and to planarize the wafer 100.

The first semiconductor material 112 is recessed or etched back from the top surface of the wafer 100 using a dry etch, as an example, to a depth within the trench 108 below the top of the substrate 106 to a depth of, for example, 1 μm. Recessing the first semiconductor material 112 trench fill defines the channel lengths of the access transistor 128 (not shown in FIG. 1; see FIG. 5), and leaves the trench isolation collar formed by first oxide layer 110 exposed in an upper part of the trench, as shown in FIG. 1.

In accordance with embodiments of the invention, the wafer 100 may be exposed to a straight ion implantation process, as shown in FIG. 2. An n type dopant, or alternatively, a p type dopant, is used to form highly doped regions 117 within a top portion of the semiconductor material 112 within the trenches 108. For n type doping, for example, arsenic or phosphorus may be used as the dopant, and for p type doping, boron may be used as the dopant, for example.

Preferably the doping of the trench semiconductor material 112 comprises a directional vertical implantation. For example, the doping may occur in an accelerator with a voltage supplied to the wafer 100 and with the dopant source being at another voltage potential. The voltage differential creates a highly directional ion implantation process in order to dope the top surface 117 of semiconductor material, without doping the sides of the trenches 108. Preferably, the trench 108 sidewalls remain undoped in accordance with an embodiment of the present invention.

Next, a reactive ion etch (RIE) or wet etch is performed to removed the top portion of the first oxide layer 110 from the trench 108 sidewalls above the first semiconductor material 112 within the trenches 108, as shown in FIG. 3. Alternatively, other types of etches may be used to remove the excess first oxide layer 110 from the region above the first semiconductor material 112 where the buried strap will be formed, to be described further herein.

In an optional step, the wafer 100 is exposed to a nitridation process, as shown in FIG. 4, to form a thin nitride layer 114 on the upper portion of the trench 108 sidewalls. In the nitridation step, the nitride layer 114 may also be formed over the exposed surfaces of the first semiconductor material 112. Preferably, the nitridation process comprises an exposure to ammonia (NH₃) at an elevated temperature, for example, between about 500-800 degrees C. for a time period of between approximately 10-30 minutes. The ammonia reacts with the exposed semiconductor material of the substrate 106 and doped semiconductor material 117, which may comprise silicon, to form a nitride layer 114 comprising 5-10 Angstroms of silicon nitride, for example.

In accordance with embodiments of the invention, a buried strap 116 is then formed or deposited on the wafer 100 in the opening in the substrate 106 above the first semiconductor material 112, as shown in FIG. 5. Preferably, the buried strap 116 deposition comprises depositing a second semiconductor material, such as silicon, in the presence of a carbon-containing gas. In the buried strap 116 deposition, a semiconductor material is deposited, for example, by low pressure chemical vapor deposition (LPCVD) in a thickness of about 20-50 nm, although alternatively, other deposition methods may be used. Preferably, during the LPCVD deposition process, propane (e.g., C₃II₈; often shown as CH₃CH₂CH₃) and a dopant such as phosphorous (preferably, using phosphine, for example) is added in-situ to a standard LPCVD polysilicon deposition. Alternatively, the dopant may comprise other chemistries such as boron or arsenic, as examples.

In accordance with embodiments of the present invention, advantageously, during the buried strap 116 deposition process, a barrier layer 126 is formed at the interface of the first semiconductor material 106 on the upper trench sidewalls, and over the first semiconductor material 112. In the embodiment shown in FIG. 5, an amount of carbon-containing gas is introduced during the deposition process such that the barrier layer 126 comprises SiₓC₁₋ₓ; that is, a 1:1 relationship does not exist between the silicon and carbon atoms. Rather, the barrier layer 126 comprises less carbon than silicon. For example, the barrier layer may comprise between around 2 to 49% carbon and between around 98 to 51% silicon, respectively.

In this embodiment, the barrier layer 126 comprises polysilicon with islands 118 of SiₓC₁₋ₓ formed therein. The buried strap 116 includes the barrier layer 126 and a polysilicon fill layer 119, as shown. While the optional nitride layer 114 is insulative, the barrier layer 126 is more conductive than the nitride layer 114 (because SiₓC₁₋ₓ is more conductive than SiN). Advantageously, the resultant barrier SiₓC₁₋ₓ layer 126 formed can be used to optimize the buried strap 116 resistance in general, while controlling the out-diffusion of dopants from the buried strap 116 into the outdiffusion region 120 of the substrate 106, shown in FIG. 5. This also allows the trench polysilicon resistance to be reduced, as it allows heavily doped phosphorus doping of the trench polysilicon, e.g., in region 117 of the polysilicon 112.

The islands 118 of SiₓC₁₋ₓ function as carbon-pinning grains to slow down the diffusion of the dopant, such as phosphorous, into the outdiffusion region 120 of the access transistor 128 formed by the gate 124, gate oxide 122 and outdiffusion region 120, which functions as a source or drain for the access transistor 128. The amount of diffusion control and slowing is modifiable by changing the amount of carbon and dopant in the buried strap 116 deposition.

The access transistor 128 includes another source or drain region 130 on an opposite side from the outdiffusion region 120, as shown in FIG. 5. Also, an optional annealing step causes some of the SiₓC₁₋ₓ atoms to migrate to the sidewalls and bottom of the buried strap 116, assisting in the formation of the barrier layer 126.

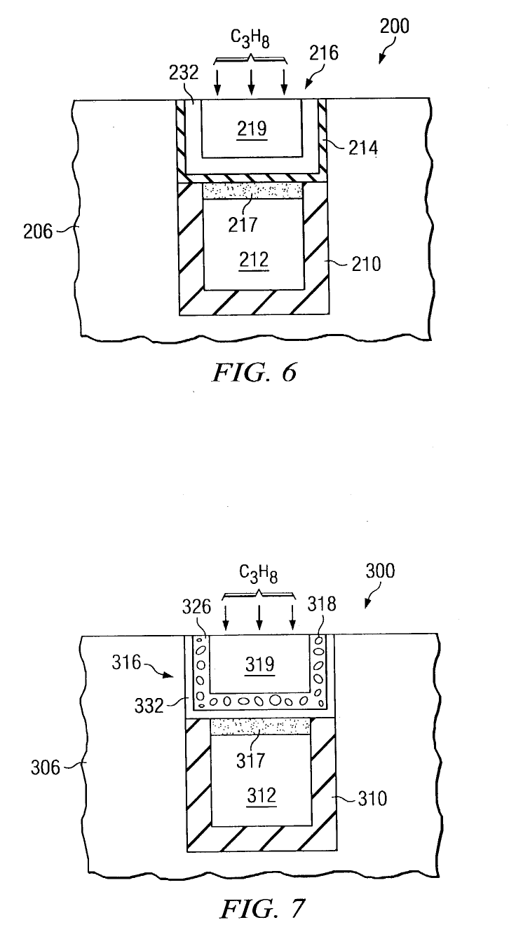

Because the barrier layer 126 controls the out-diffusion of dopants, advantageously, the nitride layer 114 is not required, but is optional, in accordance with embodiments of the present invention. For example, the nitridization step described with reference to FIG. 4 may be omitted, and a buried strap 116 comprising a SiₓC₁₋ₓ layer 126 formed directly at the interface of the substrate 106 along the trench sidewalls and over the heavily doped region 117 may be formed (not shown in FIG. 5; see FIG. 7).

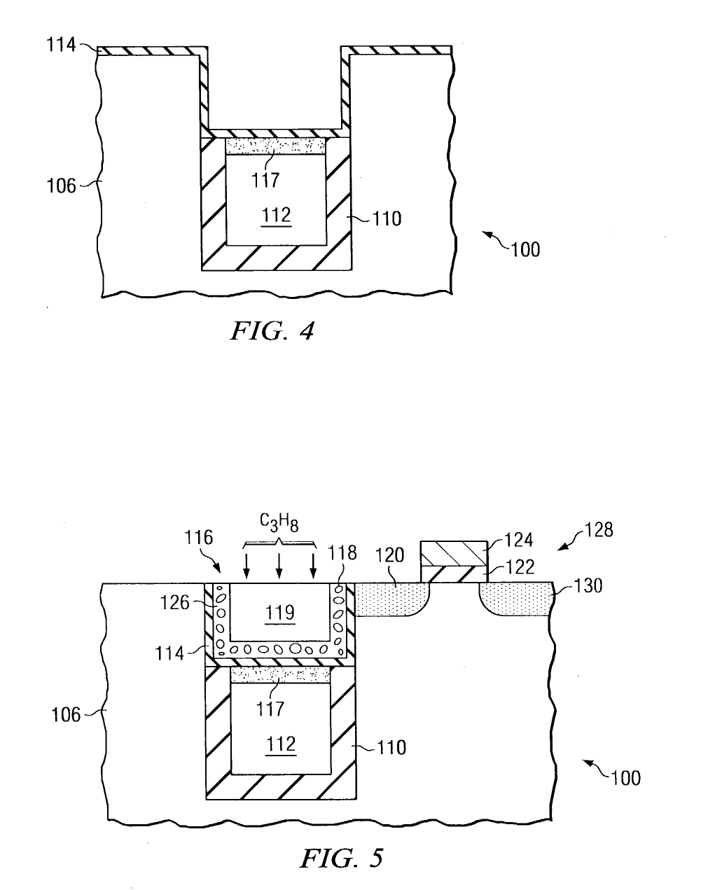

In another embodiment of the present invention, shown in FIG. 6, an amount of carbon-containing gas is introduced during the buried strap 216 deposition process such that a 1:1 relationship exists between the silicon and carbon atoms. In this embodiment, 50% of carbon is included into the buried strap 216 material, to form a barrier layer 232 comprising silicon carbide (SiC) is formed, as shown in FIG. 6. The buried strap 216 includes a semiconductor fill material 219 (comprising polysilicon, for example). The rate at which dopants travel through silicon carbide is much slower than the rate at which dopants travel through silicon. Therefore, in this embodiment, the dopant out-diffusion control into the substrate 206 region proximate the buried strap 216, and into the first semiconductor material 212 (e.g. at heavily doped region 217) is maximized.

If lower percentages of carbon are included in the buried strap 116, e.g., 2 to 49%, as shown in FIG. 5, islands or grains 118 of SiₓC₁₋ₓ are formed within the polysilicon layer 116, which slow down the dopants. Therefore, at any percentage of carbon, e.g. 2 to 50%, advantageously, dopant movement is slowed, by the introduction of carbon into the buried strap 116/216, in accordance with embodiments of the invention. Furthermore, varying deposition conditions, such as temperature and pressure, as examples, changes the grain size of the SiₓC₁₋ₓ, again allowing advantageous control of the dopant movement.

In yet another embodiment, shown in FIG. 7, two barrier layers 332 and 326 may be formed during the buried strap 316 deposition. This is accomplished by controlling the various deposition conditions. For example, a first barrier layer 332 comprising 50% carbon, e.g. SiC may be formed abutting the substrate 306 sidewalls and the top surface of heavily doped first semiconductor material 317. The second barrier layer 326 comprises less carbon than silicon, e.g., SiₓC₁₋ₓ, and may include islands 318 of SiₓC₁₋ₓ, for example. As in the other embodiments described herein, the buried strap 316 includes an inner fill material 319 comprising polysilicon, for example.

Again, for each of the embodiments described herein, the use of a nitride layer 114/214 is optional. Advantageously, because SiₓC₁₋ₓ and SiC control the out-diffusion of dopants, the use of a nitride layer is not required. The resistance of the device is lowered because SiₓC₁₋ₓ and SiC are better conductors than nitride layers. For example, in the embodiment shown in FIG. 6, a nitride layer 214 is shown; however, this nitride layer 214 may be omitted. Similarly, in the embodiment shown in FIG. 7, a nitride layer is not shown beneath the first barrier layer 332; however, a nitride layer may be formed over the substrate 306 and heavily doped semiconductor material 317 prior to forming the first barrier layer 332.

The wafer 100 may optionally be annealed, for example, at a temperature of 950 degrees C. for 30 seconds, (although alternatively, other temperatures and times may be used), which causes outdiffusion of dopants from the buried strap 116 into the outdiffusion region 120. However, this anneal is not required. The wafer 100/200/300 may be exposed to anneals in subsequent processing steps, which may cause further outdiffusion of dopants.

The buried strap 116/216/316 may then be recessed, e.g., by approximately 30 nm, for example, to prepare for the formation of a trench top oxide (TTO), for example, not shown. Other processing steps are subsequently performed, such as the formation of shallow trench isolation regions, as an example, also not shown.

Embodiments of the invention achieve technical advantages by providing the ability to control the crystalline structure and carbon content in the SiₓC₁₋ₓ film 126/326 of the buried strap 116/216/316. The dopant and carbon content of the buried strap 116/216/316 are preferably in-situ doped, and is easily annealed and etched. The carbon content and dopant of the buried strap 116/216/316 may be varied, allowing the formation of a conducting interface 126/232/326/332 and the inhibition of re-crystallization of the region of buried strap/outdiffusion area of substrate interface, by carbon pinning grains 118/318 that are formed in the buried strap 116/216/316.

Another advantage of embodiments of the invention is that the carbon in the buried strap 116/216/316 allows the top portion 117/217/317 of the deep trench semiconductor fill material 112/212/312 to be more heavily doped, which reduces the trench semiconductor material resistance. Furthermore, preferably a low pressure chemical vapor deposition (LPCVD) deposition process is used, which advantageously requires a low temperature and pressure. Outdiffusion of dopants from the buried strap 116/216/316 may be controlled by varying the carbon content of the buried strap, and the resistance of the buried strap may be lowered, particularly at low temperatures.

While embodiments of the present invention are described herein with reference to a DRAM, they also have useful application in ferroelectric random access memory (FRAM) devices and other semiconductor devices. Although an access transistor 128 is only shown in FIG. 5, each embodiment includes an access transistor for each DRAM memory cell (not shown).

Although embodiment of the present invention and their advantages have been described in detail, it should be understood that various changes, substitutions and alterations can be made herein without departing from the spirit and scope of the invention as defined by the appended claims. For example, it will be readily understood by those skilled in the art that the processes and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method for forming a buried strap of a memory device, comprising:
providing a memory device, the memory device having a substrate with at least one trench capacitor formed therein, the trench capacitor including a fill material comprising a first semiconductor material;
recessing the first semiconductor material of the at least one trench capacitor below a top surface of the substrate; and
depositing a second semiconductor material over the recessed first semiconductor fill material in the presence of a carbon-containing gas, wherein the second semiconductor material forms a buried strap.

2. The method according to claim 1, further comprising doping the top of the first semiconductor material, prior to forming the buried strap.

3. The method according to claim 1, wherein the carbon-containing gas comprises butane.

4. The method according to claim 1, wherein depositing the second semiconductor material is in the presence of a dopant.

5. The method according to claim 4, wherein the dopant comprises phosphorous, arsenic or boron.

6. The method according to claim 4, further comprising annealing the memory device, causing the dopant to diffuse into an outdiffusion region proximate an upper portion of the trench.

7. The method according to claim 1, wherein the carbon-containing gas results in the formation of SiₓC₁₋ₓ in the buried strap.

8. The method according to claim 8, wherein the carbon content comprises 2 to 49% of the buried strap material.

9. The method according to claim 1, wherein the carbon-containing gas results in the formation of SiC in the buried strap.

10. The method according to claim 1, wherein the carbon-containing gas causes a barrier layer to form proximate the outdiffusion region along the edge of the upper portion of the trench and along the bottom of the buried strap, wherein the barrier layer comprises carbon.

11. A method of manufacturing a memory device, comprising:
providing a workpiece, the workpiece comprising a semiconductor material substrate;
forming at least one memory cell within the workpiece, the at least one memory cell comprising a trench capacitor, the trench capacitor including a fill material comprising a first semiconductor material;
recessing the first semiconductor material of the at least one trench capacitor below a top surface of the substrate; and
depositing a second semiconductor material over the recessed first semiconductor fill material in the presence of a carbon-containing gas and a dopant, wherein the second semiconductor material forms a buried strap.

12. The method according to claim 11, wherein the buried strap comprises carbon.

13. The method according to claim 12, wherein the buried strap comprises 2 to 50% carbon.

14. The method according to claim 12, wherein the carbon in the buried strap is adapted to control the diffusion of the dopant into an outdiffusion region of the substrate proximate the buried strap.

15. The method according to claim 14, wherein the carbon resides in a barrier layer proximate at least the outdiffusion region of the substrate.

16. The method according to claim 11, further comprising doping the top of the first semiconductor material, prior to forming the buried strap.

17. The method according to claim 11, wherein the carbon-containing gas comprises butane.

18. The method according to claim 11, wherein the dopant comprises phosphorous, arsenic or boron.

19. The method according to claim 11, further comprising annealing the memory device, causing the dopant to diffuse into an outdiffusion region proximate an upper portion of the trench.

20. A memory device, comprising:
a workpiece, the workpiece comprising a semiconductor material substrate;
at least one memory cell within the workpiece, the at least one memory cell comprising a trench capacitor, the trench capacitor including a fill material comprising a first semiconductor material, the fill material being recessed below a top surface of the substrate; and
a second semiconductor material disposed over and abutting the recessed first semiconductor fill material, wherein the second semiconductor material forms a buried strap, wherein the second semiconductor material comprises a dopant and carbon.

21. The memory device according to claim 20, wherein the buried strap comprises 2 to 50% carbon.

22. The memory device according to claim 20, wherein the carbon in the buried strap is adapted to control diffusion of the dopant into the outdiffusion region.

23. The memory device according to claim 20, wherein a top surface of the fill material is heavily doped.

24. The memory device according to claim 20, wherein the buried strap carbon resides in a barrier layer formed at the top portion of the trench between the second semiconductor material and the substrate and along the bottom of the buried strap.
